(19) United States
(12) Patent Application Publication
(10) Pub. No.: US 2025/0267897 A1
(43) Pub. Date: Aug. 21, 2025

(54) THIN FILM TRANSISTOR WITH TRENCH-STRUCTURED OXIDE SEMICONDUCTOR LAYERS AND METHOD OF MANUFACTURING SAME

(71) Applicant: Korea Research Institute of Standards and Science, Daejeon (KR)

(72) Inventors: Moo Kyum KIM, Daejeon (KR); Min Seok Kim, Daejeon (KR); Seong Gu Hong, Daejeon (KR)

(21) Appl. No.: 18/760,163

(22) Filed: Jul. 1, 2024

(30) Foreign Application Priority Data
Feb. 15, 2024 (KR) 10-2024-0021573

(51) Int. Cl. H01L 29/786; H01L 29/417; H01L 29/66

(52) U.S. Cl. CPC H10D 30/6755; H10D 30/0321; H10D 30/6729

(57) ABSTRACT

A thin film transistor with trench-structured oxide semiconductor layers includes the substrate, the source electrode, the drain electrode, a first oxide semiconductor layer, a second oxide semiconductor layer, the gate insulating layer, and the gate electrode, and a method of manufacturing the same. The method of manufacturing the thin film transistor with trench-structured oxide semiconductor layers composed of thin and thick segments includes arranging the source electrode and the drain depositing first oxide electrode on the substrate, a semiconductor layer on the source electrode and the drain electrode, depositing a second oxide semiconductor layer on the first oxide semiconductor layer, forming the gate insulator layer on the second oxide semiconductor layer, and forming the gate electrode on the gate insulator layer. The trench structure is formed by the first oxide semiconductor layer and the second oxide semiconductor layer to have high field-effect mobility.

### CROSS REFERENCE TO RELATED APPLICATION

The present application claims priority to Korean Patent Application No. 10-2024-0021573, filed Feb. 15, 2024, the entire contents of which is incorporated herein for all purposes by this reference.

### BACKGROUND OF THE INVENTION

### Field of the Invention

The present invention relates to a thin film transistor with trench-structured oxide semiconductor layers and method of manufacturing, and more specifically, to the thin film transistor with trench-structured oxide semiconductor layers in which the thickness and length of the channel layer are adjusted and uniformity of performance between thin film transistor dies across the entire wafer is improved by depositing and finely patterning a first oxide thin film layer on a substrate and forming and finely patterning a second oxide thin film layer using atomic layer deposition, and a method of manufacturing the same.

### Description of the Related Art

The thin film transistor is a type of field effect transistor manufactured by stacking a semiconductor thin film on an insulating substrate. The thin film transistor includes a substrate, a source electrode, a drain electrode, an oxide semiconductor layer, a gate insulator layer, and gate electrode. When a voltage is applied to the gate electrode, holes gather between the source electrode and the drain electrode to form a channel, and a current flow from the source electrode to the drain electrode. Materials that form the channel layer of the thin film transistor include amorphous silicon, low-temperature polycrystalline silicon, oxide, and the like. Among these, the thin film transistor whose channel layer is made of oxide is referred to as an oxide thin film transistor. Oxides used in the oxide thin film transistor include indium-zinc-oxide (In—Zn—O, IZO), indium-gallium-zinc-oxide (In—Ga—Zn—O, IGZO), indium-tin-gallium-oxide (In—Sn—Zn—O, ITZO), and the like.

Thin film transistors are used in liquid crystal display devices. To implement display devices, it is essential to develop the performance of thin film transistors with high field-effect mobility. Conventional thin film transistors have improved field-effect mobility compared to a planar structure by forming a trench structure using a difference in deposition rate between vertical sections and horizontal sections, which is caused by dry etching of a silicon substrate and depositing an oxide semiconductor layer, to decrease a length of the channel layer. However, such a process has limitations in that the thickness and length of the channel layer may not be adjusted, and due to the dry etching of a wafer substrate, there is a problem in that the process may be performed with only the silicon substrate and uniformity of performance between thin film transistor dies across the entire wafer is degraded.

### SUMMARY OF THE INVENTION

The present invention addresses the problems and is directed to providing a technology of manufacturing the trench-structured oxide semiconductor layers composed of thin and thick segments in the process of forming the thin film transistor.

In addition, the present invention is directed to providing a technology about the thin film transistor with trench-structured oxide semiconductor layers, which may have high mobility by forming the trench structure by which the thickness and length of the channel layer are adjusted and uniformity of performance between thin film transistor dies across the entire wafer is improved by depositing and finely patterning the oxide semiconductor layer without dry etching of the wafer substrate, and a method of manufacturing the same.

The objects of the present invention are not limited thereto and also include objects or effects that can be identified from the technical solution or embodiments, which will be described below.

A method of manufacturing the thin film transistor with trench-structured oxide semiconductor layers according to one embodiment of the present invention includes arranging the source electrode and the drain electrode on the substrate, depositing a first oxide semiconductor layer on the source electrode and the drain electrode, depositing a second oxide semiconductor layer on the first oxide semiconductor layer, forming the gate insulator layer on the second oxide semiconductor layer, and forming the gate electrode on the gate insulator layer, wherein the trench structure is formed by the first oxide semiconductor layer and the second oxide semiconductor layer to have high field-effect mobility.

The substrate may include one or more among a silicon wafer, a glass wafer, a polyethylene terephthalate film, a polymethyl methacrylate film, and a polyimide film.

The first oxide semiconductor layer and the second oxide semiconductor layer may include one or more among InGaZnO, ZnO, ZrInZnO, InZnO, AlInZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, and TiSrO₃.

The deposition of the first oxide semiconductor layer may include depositing the first oxide semiconductor layer by including one or more among sputtering, chemical vapor deposition, atomic layer deposition, and a solution process.

The thickness of the first oxide semiconductor layer may be in the range of 1 nm to 100 nm on the substrate, the source electrode, and the drain electrode.

The first oxide semiconductor layer may include a structure with a surface or portion finely patterned.

The finely patterned structure may include a structure in which at least one step or groove is formed above the first oxide semiconductor.

The deposition of the second oxide semiconductor layer may include forming the second oxide semiconductor layer in the thickness of 1 nm to 30 nm on the finely patterned first oxide semiconductor layer.

The deposition of the second oxide semiconductor layer may include forming the second oxide semiconductor using atomic layer deposition.

The second oxide semiconductor layer may include a structure with a surface or portion finely patterned.

The method of manufacturing the thin film transistor with trench-structured oxide semiconductor layers composed of thin and thick segments according to one embodiment of the present invention may further include thermally treating the first oxide semiconductor layer and the second oxide semiconductor layer in the range of 100° C. to 500° C.

The thin film transistor with trench-structured oxide semiconductor layers according to one embodiment of the present invention includes the substrate, the source electrode and the drain electrode that are disposed on the substrate, a first oxide semiconductor layer that are deposited on the source electrode and the drain electrode, a second oxide semiconductor layer deposited on the first oxide semiconductor layer, the gate insulator layer formed on the second oxide semiconductor layer, and the gate electrode formed on the gate insulator layer, wherein the trench structure is formed by the first oxide semiconductor layer and the second oxide semiconductor layer to have high field-effect mobility.

### BRIEF DESCRIPTION OF THE DRAWINGS

FIG. 1 shows the structure of the thin film transistor with trench-structured oxide semiconductor layers according to the embodiment of the present invention.

FIG. 2 shows a method of manufacturing the thin film transistor with trench-structured oxide semiconductor layers composed of thin and thick segments according to the embodiment of the present invention.

FIG. 3 is a schematic diagram schematically showing a method of forming the source electrode and the drain electrode on the substrate according to the embodiment of the present invention.

FIG. 4 is a schematic diagram schematically showing a method of forming a first oxide semiconductor layer on the source electrode and the drain electrode according to the present invention, finely patterned as the trench structure.

FIG. 5 is a schematic diagram showing a method of acquiring a second oxide semiconductor layer formed on the first oxide semiconductor layer according to the embodiment of the present invention.

FIG. 6 is a schematic diagram showing a method of acquiring the gate insulator layer formed on the second oxide semiconductor layer according to the embodiment of the present invention.

FIG. 7 is a schematic diagram showing a method of acquiring the gate electrode formed on the gate insulator layer according to the embodiment of the present invention and a view showing the thin film transistor with trench-structured oxide semiconductor layers composed of thin and thick segments.

FIG. 8 is a view showing one embodiment of a structure in which a depth is formed by finely patterning a surface or portion of the first oxide semiconductor layer according to the embodiment of the present invention.

FIG. 9 is a view showing another embodiment of the structure in which the depth is formed by finely patterning the surface or portion of the first oxide semiconductor layer according to the embodiment of the present invention.

### DETAILED DESCRIPTION OF THE INVENTION

Hereinafter, exemplary embodiments according to the present invention will be described in detail with reference to the accompanying drawings.

However, the technical spirit of the present invention is not limited to some of the described embodiments, but may be implemented in various different forms, and one or more of the components among the embodiments may be used by being selectively coupled or substituted without departing from the scope of the technical spirit of the present invention.

In addition, terms (including technical and scientific terms) used in embodiments of the present invention may be construed as meaning that may be generally understood by those skilled in the art to which the present invention pertains unless explicitly specifically defined and described, and the meanings of the commonly used terms, such as terms defined in a dictionary, may be construed in consideration of contextual meanings of related technologies.

In addition, the terms used in the embodiments of the present invention are for describing the embodiments and are not intended to limit the present invention.

In the specification, a singular form may include a plural form unless otherwise specified in the phrase, and when described as “at least one (or one or more) of A, B, and C,” one or more among all possible combinations of A, B, and C may be included.

In addition, the terms, such as first, second, A, B, (a), and (b) may be used to describe components of the embodiments of the present invention.

These terms are only for the purpose of distinguishing one component from another component, and the nature, sequence, order, or the like of the corresponding components is not limited by these terms.

In addition, when a first component is described as being “connected,” “coupled,” or “joined” to a second component, it may include a case in which the first component is directly connected, coupled, or joined to the second component, but also a case in which the first component is “connected,” “coupled,” or “joined” to the second component by other components present between the first component and the second component.

In addition, when a certain component is described as being formed or disposed on “on (above)” or “below (under)” another component, the terms “on (above)” or “below (under)” may include not only a case in which two components are in direct contact with each other, but also a case in which one or more other components are formed or disposed between the two components. In addition, when described as “on (above) or below (under),” it may include the meaning of not only an upward direction but also a downward direction based on one component.

Hereinafter, exemplary embodiments of the present invention will be described in detail with reference to the accompanying drawings. The same components in the drawings use the same reference numerals, and overlapping descriptions of the same components will be omitted.

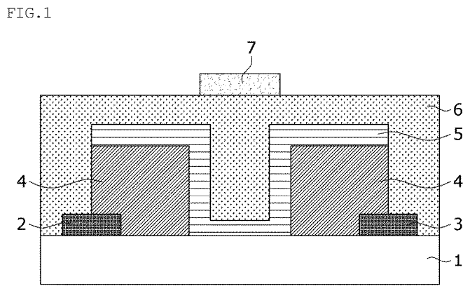

FIG. 1 shows a structure of the trench-structured oxide semiconductor layers composed of thin and thick segments according to the embodiment of the present invention.

Referring to FIG. 1, the thin film transistor with trench-structured oxide semiconductor layers may include the substrate 1, the source electrode 2, the drain electrode 3, the first oxide semiconductor layer 4, the second oxide semiconductor layer 5, the gate insulator layer 6, and the gate electrode 7.

The substrate 1 may include one or more among the silicon wafer, the glass wafer, the polyethylene terephthalate film, the polymethyl methacrylate film, and the polyimide film.

The source electrode 2 and the drain electrode 3 may be disposed on one surface of the substrate 1 and may be made of the same material. However, the present invention is not limited thereto. The source electrode 2 and the drain electrode 3 are distinguished for convenience of description and may be interchanged.

The first oxide semiconductor layer 4 may be finely patterned to form the trench structure, thereby having high field-effect mobility. The finely patterned structure may be included on a surface or portion of the first oxide semiconductor layer 4. The finely patterned structure may include a structure in which one or more steps or grooves are formed.

The first oxide semiconductor layer 4 and the second oxide semiconductor layer 5 may include one or more among InGaZnO, ZnO, ZrInZnO, InZnO, AlInZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, and TiSrO₃. However, embodiments of the present invention are not limited thereto, and other oxide semiconductor materials known in the art may be included.

According to one embodiment, the first oxide semiconductor layer 4 and the second oxide semiconductor layer 5 may be made of the same material or different materials.

The gate insulator layer 6 may electrically block the gate electrode 7 from other components, that is, the substrate 1, the source electrode 2, the drain electrode 3, the first oxide semiconductor layer 4, and the second oxide semiconductor layer 5. The gate insulator layer 6 may include an insulating material, such as silicon oxide or silicon nitride. For example, aluminum oxide (Al2O3) may be used as the insulating film 6.

The gate electrode 7 may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum or a molybdenum alloy, chromium (Cr), tantalum (Ta), neodymium (Nd), and titanium (Ti).

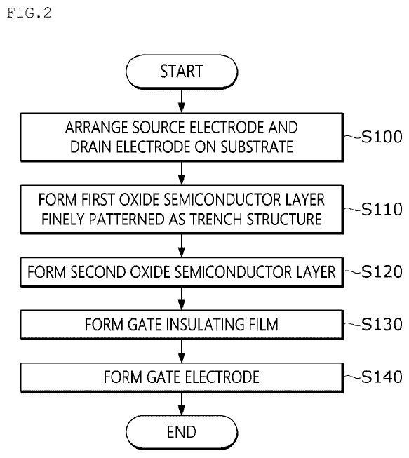

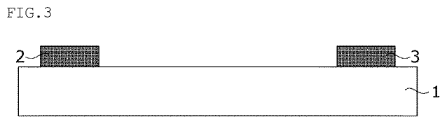

FIG. 2 is a flowchart showing a method of manufacturing the thin film transistor with trench-structured oxide semiconductor layers composed of thin and thick segments according to the embodiment of the present invention, and FIGS. 3 to 7 are schematic diagrams schematically showing each operation of FIG. 2.

Hereinafter, each operation of FIG. 2 will be described with reference to FIGS. 3 to 7.

First, referring to FIG. 2, the source electrode 2 and the drain electrode 3 are disposed on the substrate 1 (S100). As shown in FIG. 3, the source electrode 2 and the drain electrode 3 may be disposed on the substrate 1. The substrate 1 may include one or more among the silicon wafer, the glass wafer, the polyethylene terephthalate film, the polymethyl methacrylate film, and the polyimide film.

According to one embodiment, an annealing process may be performed on the substrate 1, and at this time, a temperature may be in the range of 200° C. to 350° C.

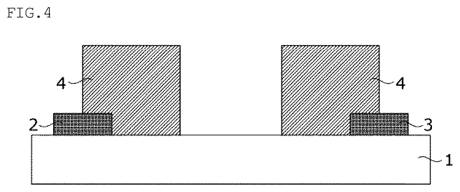

Next, referring to FIGS. 2 and 4, the first oxide semiconductor layer 4 is deposited on the source electrode 2 and the drain electrode 3 (S110). The first oxide semiconductor layer 4 is finely patterned to form the trench structure, thereby having high field-effect mobility. According to the trench structure, the thin film transistor may have high field-effect mobility. The first oxide semiconductor layer 4 may include one or more among InGaZnO, ZnO, ZrInZnO, InZnO, AlInZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, and TiSrO₃, but is not limited thereto. One or more among sputtering, chemical vapor deposition, atomic layer deposition, and a solution process may be used to deposit the first oxide semiconductor layer 4. The first oxide semiconductor layer 4 may be deposited in a thickness of 1 nm to 100 nm.

According to one embodiment, the first oxide semiconductor layer 4 may be thermally treated in the range of 100° C. to 500° C.

According to one embodiment, the first oxide semiconductor layer 4 may include a structure with a surface or portion finely patterned. The finely patterned structure may include a structure in which at least one step or groove is formed above the first oxide semiconductor layer 4.

According to one embodiment, a distance between steps or grooves on the substrate may be in the range of 1 μm to 10 μm.

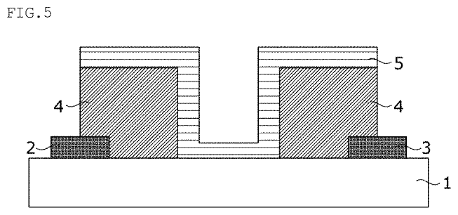

Next, referring to FIGS. 2 and 5, the second oxide semiconductor layer 5 is deposited on the first semiconductor layer 4. The second oxide semiconductor layer 5 may also include one or more among InGaZnO, ZnO, ZrInZnO, InZnO, AlInZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, and TiSrO₃, but is not limited thereto. The second oxide semiconductor layer 5 may be deposited by, for example, atomic layer deposition. The second oxide semiconductor layer 5 may be manufactured on the first oxide semiconductor layer 4 in a thickness of 1 nm to 30 nm.

According to one embodiment, the second oxide semiconductor layer 5 may be thermally treated in the range of 100° C. to 500° C.

According to one embodiment, the second oxide semiconductor layer 5 may include a structure with a surface or portion finely patterned.

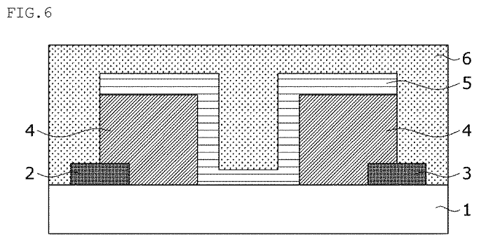

Next, referring to FIGS. 2 and 6, the gate insulator layer 6 is deposited on the second semiconductor layer 5 (S130). For example, the gate insulator layer 6 may include aluminum oxide (Al2O3), but the type of material forming the gate insulator layer 6 is not limited thereto.

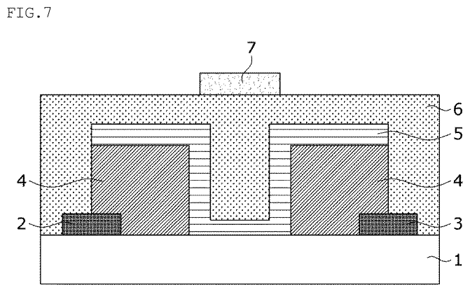

Next, referring to FIGS. 2 and 7, the gate electrode 7 is deposited on the gate insulator layer 6 (S140). The gate electrode 7 may include, for example, molybdenum (Mo), but the type of material forming the gate electrode 7 is not limited thereto.

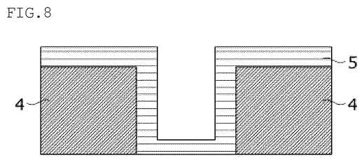

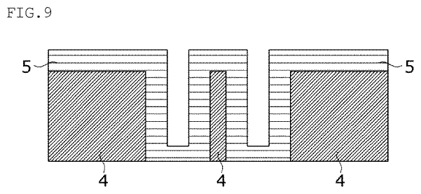

Lastly, FIGS. 8 and 9 show some of several examples of structures in which a depth is formed by finely patterning the surface or portion of the first oxide semiconductor layer 4 according to the embodiment of the present invention.

According to the present invention, it is possible to provide the technology of manufacturing the trench-structured oxide semiconductor layers composed of thin and thick segments.

In addition, the thin film transistor with trench-structured oxide semiconductor layers composed of thin and thick segments according to the present invention has high field-effect mobility.

According to the present invention, it is possible to improve field-effect mobility by decreasing the length of the channel layer due to the non-uniform deposition phenomenon that occurs upon deposition after dry etching.

In addition, it is possible to provide the technology of improving the uniformity of performance between thin film transistor dies across the entire wafer by forming the structure without dry etching of the wafer substrate.

Although embodiments have been mainly described above, these are only illustrative and do not limit the present invention, and those skilled in the art to which the present invention pertains can know that various modifications and applications not exemplified above are possible without departing from the essential characteristics of the embodiments. For example, each component specifically illustrated in the embodiments may be implemented by modification. In addition, differences related to these modifications and applications should be construed as being included in the scope of the present invention defined in the appended claims.

### DESCRIPTION OF REFERENCE NUMERALS

1: substrate 2: source electrode
3: drain electrode 4: first oxide semiconductor layer
5: second oxide semiconductor layer 6: gate insulator layer
7: gate electrode

What is claimed is:

1. A method of manufacturing the thin film transistor with trench-structured oxide semiconductor layers, comprising:
arranging the source electrode and the drain electrode on the substrate;
depositing a first oxide semiconductor layer on the source electrode and the drain electrode;
depositing a second oxide semiconductor layer on the first oxide semiconductor layer;
forming the gate insulator layer on the second oxide semiconductor layer; and
forming the gate electrode on the gate insulator layer,
wherein the trench structure is formed by the first oxide semiconductor layer and the second oxide semiconductor layer to have high field-effect mobility.

2. The method of claim 1, wherein the substrate includes one or more among the silicon wafer, the glass wafer, the polyethylene terephthalate film, the polymethyl methacrylate film, and the polyimide film.

3. The method of claim 1, wherein the first oxide semiconductor layer and the second oxide semiconductor layer include one or more among InGaZnO, ZnO, ZrInZnO, InZnO, AlInZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, and TiSrO₃.

4. The method of claim 1, wherein the deposition of the first oxide semiconductor layer includes depositing the first oxide semiconductor layer by including one or more among sputtering, chemical vapor deposition, atomic layer deposition, and a solution process.

5. The method of claim 1, wherein the thickness of the first oxide semiconductor layer is in the range of 1 nm to 100 nm on the substrate, the source electrode, and the drain electrode.

6. The method of claim 1, wherein the first oxide semiconductor layer includes a structure with a surface or portion finely patterned.

7. The method of claim 6, wherein the finely patterned structure includes a structure in which at least one step or groove is formed above the first oxide semiconductor layer.

8. The method of claim 1, wherein the deposition of the second oxide semiconductor layer includes forming the second oxide semiconductor layer in the thickness of 1 nm to 30 nm on the finely patterned first oxide semiconductor layer.

9. The method of claim 1, wherein the deposition of the second oxide semiconductor layer includes forming the second oxide semiconductor using atomic layer deposition.

10. The method of claim 9, wherein the second oxide semiconductor layer includes a structure with a surface or portion finely patterned.

11. The method of claim 1, further comprising thermally treating the first oxide semiconductor layer and the second oxide semiconductor layer in the range of 100° C. to 500° C.

12. A thin film transistor with trench-structured oxide semiconductor layers, comprising:
a substrate;
a source electrode and a drain electrode that are disposed on the substrate;
a first oxide semiconductor layer deposited on the source electrode and the drain electrode;
a second oxide semiconductor layer deposited on the first oxide semiconductor layer;
a gate insulator layer formed on the second oxide semiconductor layer; and
a gate electrode formed on the gate insulator layer,
wherein the trench structure is formed by the first oxide semiconductor layer and the second oxide semiconductor layer to have high field-effect mobility.
